(19) United States
(12) Patent Application Publication
(10) Pub. No.: US 2018/0351049 A1
(43) Pub. Date: Dec. 6, 2018

(54) WAVELENGTH CONVERSION PHOSPHOR

(71) Applicant: Panasonic Corporation, Osaka (JP)

(72) Inventors: MASATO MORI, Hyogo (JP); KAZUHIRO NISHIKAWA, Osaka (JP); KEI TOYOTA, Osaka (JP); SHINNOSUKE AKIYAMA, Osaka (JP); TSUGUO FUKUDA, Miyagi (JP)

(21) Appl. No.: 15/991,740

(22) Filed: May 29, 2018

(30) Foreign Application Priority Data
Jun. 6, 2017 (JP) 2017-111956

(51) Int. Cl. H01L 33/50; C04B 35/653; C09K 11/77

(52) U.S. Cl. CPC H01L 33/502; H01L 33/505; C04B 35/653; C09K 11/7743; C09K 11/7715; C09K 11/7756; C09K 11/7728

(57) ABSTRACT

A wavelength conversion phosphor having a wavelength conversion function, which is high in fluorescence output and excellent in heat resistance. The wavelength conversion phosphor including a first metal oxide phase as a phosphor phase containing activated metal ions which emit fluorescence, and a second metal oxide phase adjacent to the first metal oxide phase through an interface, in which a concentration of the activated metal ions in the interface is higher than a concentration of the activated metal ions contained in the first metal oxide phase.

### TECHNICAL FIELD

The technical field relates to a wavelength conversion phosphor used for a white LED (Light Emitting Diode), a white laser light source and so on.

### BACKGROUND

In recent years, blue diodes are practically used and blue LEDs have begun to be mass produced. Together with red and green, the three primary colors of light realize a white color in LEDs. The white LED is used for light sources for general lighting by realization of high luminance, high output and high efficiency in lighting equipment.

A light source with higher output is required with respect to high luminance of a projector as a light source and for distant lighting as car headlights. The use of a blue laser diode (LD) as an excitation light source instead of an LED light source is also being considered.

In particular, the unit price of the LD light source is decreasing as a ripple effect of the practical realization of a laser display. Therefore, development of laser lighting such as laser headlights of the car, intelligent lighting and endoscope lighting has started. The LD is capable of easily collecting light by a lens or a mirror. The LD is also capable of concentrating light on a minute area.

However, when a power density of excitation light is increased, light energy is concentrated to a minute area and a heat generation amount is increased. Accordingly, a phosphor which is excellent in heat resistance and high in fluorescence output is required. Reduction in fluorescence output (temperature quenching) at the time of high temperature is becoming a more serious problem particularly in laser lighting using LD as the excitation light source than in LED lighting of related art.

In the white LED in related art, in a YAG, Ce phosphor using Ce³⁺ as an activated metal absorbs blue excitation light with a peak wavelength of 450 nm emitted from an InGaN-based semiconductor and outputs yellow light having a peak in the vicinity of 550 nm as fluorescence. That is, white light can be realized by mixing blue light and yellow light.

In a YAG, the Ce phosphor in related art is formed by sintering an oxide such as Al₂O₃, Y₂O₃ or CeO₂. However, there is a problem that a fluorescence output is rapidly reduced as a phosphor characteristic when the temperature of the phosphor is increased to approximately 100° C. to 150° C.

### SUMMARY

In order to solve the above problem, a single-crystal phosphor with YAG crystals as a matrix is disclosed in Japanese Patent No. 5649201 (Patent Literature 1), in which a wavelength of excitation light is 460 nm and a reduction in fluorescence intensity (fluorescence output) obtained when the temperature is increased from 25° C. to 100° C. is less than 3%.

Disclosed in Japanese Patent No. 4609319 (Patent Literature 2), a wavelength conversion material is generated from two or more kinds of metal oxide matrix phases. The respective matrix phases are arranged continuously, three-dimensionally and existing while being entangled with one another. In this disclosure, a wavelength conversion material including a ceramic composite material in which at least one of matrix phases is a phosphor phase containing an activated oxide is disclosed.

However, the phosphor disclosed in Patent Literature 1 is a single crystal phosphor. Therefore, the phosphor contains only 0.06 at % of activated metal ions Ce³⁺ emitting fluorescence, which is a theoretical limit with respect to a Y (Yttrium) site of a YAG single crystal.

Accordingly, there is a problem in that the fluorescence output is saturated and low because the content of the activated metal ions Ce³⁺ absorbing the excitation light when the output is increased is low. Though, the reduction in fluorescence output is small. For example, when there are sufficient activated metal ions to reach the theoretical limit, in a case where 1 AmW of excitation light (for example, a wavelength of 450 nm) is incident on the blue LD with a conversion efficiency of 95%, light emission by wavelength conversion of 0.95 AmW is possible in a wavelength region of yellow (for example, wavelengths 570 to 590 nm).

However, even when excitation light with high output is incident and excited with the conversion efficiency of 95%, unconverted excitation light penetrates, and it is difficult to emit yellow wavelength light with 95% conversion efficiency. In the case where the content of the activated metal ions Ce³⁺ is not sufficient, it is difficult to emit yellow wavelength light with the conversion efficiency of 95% expected based on an original conversion efficiency.

As only 0.06 at % of the activated metal ions Ce³⁺ as the theoretical limit are contained with respect to the Y (Yttrium) site of YAG as the matrix as described above, it is difficult to obtain a high fluorescence output.

In the light conversion member described in Patent Literature 2, a taking-out speed from a heating region of a crucible, namely, a solidification rate of a melt is set to an appropriate value based on a composition of the melt and melting conditions, which is normally 50 mm/h or less, preferably 1 to 20 mm/h.

Accordingly, only 0.06 at % of the activated metal ions Ce³⁺ as the theoretical limit are contained with respect to the Y (Yttrium) site of YAG as the matrix as a metal oxide is crystallized also in Patent Literature 2 in the same manner as in Patent Literature 1.

Accordingly, there is also the problem that it is difficult to obtain a high fluorescence output in Patent Literature 2 in the same manner as in Patent Literature 1, although the heat resistance is high due to the ceramic composite material.

In order to solve the above problems, as well as other concerns, the present disclosure concerns a material capable of obtaining high-output yellow fluorescence by absorbing blue light emitted by excitation light of the LED or the LD (appropriately 400 to 480 nm) as well as having excellent heat resistance.

An object of the present disclosure is to provide a wavelength conversion phosphor having a wavelength conversion function, generating fluorescence, having a high fluorescence output, and corresponding to light collection using a high-energy LD as an excitation light source. The wavelength conversion function is namely the function of absorbing light having a certain wavelength. Generating fluorescence is generating light having a wavelength different from the wavelength of absorbed light. High fluorescence output is namely high luminance.

A wavelength conversion phosphor according to the present disclosure includes a first metal oxide phase as a phosphor phase containing activated metal ions which emit fluorescence and a second metal oxide phase adjacent to the first metal oxide phase through an interface, in which a concentration of the activated metal ions in the interface is higher than a concentration of the activated metal ions contained in the first metal oxide phase.

As described above, the wavelength conversion phosphor according to the present disclosure has the wavelength conversion function, high fluorescence output and excellent heat resistance.

### BRIEF DESCRIPTION OF THE DRAWINGS

FIG. 1 is a schematic view of a cross section of a wavelength conversion phosphor according to Embodiment 1.

(a) of FIG. 2 is a picture of cross-sectional observation of the wavelength conversion phosphor, (b) of FIG. 2 is an enlarged picture of cross-sectional observation of part of (a) of FIG. 2, and (c) of FIG. 2 shows results of analyzing elemental compositions in a bright part, a dark part and an interface between the bright part and the dark park in (b) of FIG. 2.

FIG. 3A is a schematic view showing a device and a process for manufacturing the wavelength conversion phosphor according to Embodiment 1, which is an outline diagram showing a state where a melt is allowed to contact a seed crystal.

FIG. 3B is a schematic view showing a device and a process for manufacturing the wavelength conversion phosphor according to Embodiment 1, which is an outline diagram showing a state where the seed crystal is pulled down to grow a crystal on the seed crystal.

(a) of FIG. 4 is an outline diagram showing a structure of a measurement device for measuring the fluorescence output (external quantum efficiency) of the wavelength conversion phosphor, and (b) of FIG. 4 is a partial outline diagram between a lens and a lens of the measuring device.

FIG. 5 is a graph showing variations of a fluorescence output ratio with respect to temperatures in Comparative Examples and Example.

### DESCRIPTION OF EMBODIMENTS

A wavelength conversion phosphor according to an embodiment includes a first metal oxide phase as a phosphor phase containing activated metal ions which emit fluorescence and a second metal oxide phase adjacent to the first metal oxide phase through an interface, in which a concentration of the activated metal ions in the interface is higher than a concentration of the activated metal ions contained in the first metal oxide phase.

In the wavelength conversion phosphor according to another aspect, the first metal oxide phase and the second metal oxide phase may form a eutectic structure on the interface.

In the wavelength conversion phosphor according to another aspect, the first metal oxide phase and the second metal oxide phase may respectively have portions having dimensions of 1 μm or less in the eutectic structure.

In the wavelength conversion phosphor according to another aspect, the activated metal ions which emit fluorescence may include one or more kinds of metal ions selected from a group of La³⁺, Y³⁺, Ce³⁺, Nd³⁺, Gd³⁺, Eu²⁺, Eu³⁺, Tb²⁺, Ho³⁺, Er³⁺, Tm³⁺, Tb³⁺ and Lu³⁺, the first metal oxide phase may include one or more kinds of metal oxides selected from a group of La₂O₃, Y₂O₃, Y₃Al₅O₁₂, CeO₂, Nd₂O₃, Gd₂O₃, Eu₂O₃, Tb₄O₇, Ho₂O₃, Er₂O₃, Tm₂O₃, Yb₂O₃, Lu₂O₃ and Cr₂O₃, the second metal oxide phase may include one or more kinds of metal oxides selected from a group of Al₂O₃, MgO, SiO₂, TiO₂, ZrO₂, Y₂O₃, MnO, Nb₂O₅, Cr₂O₃, SrO, ZnO and SnO₂, and the activated metal ions may be contained in the interface in higher concentration than an average concentration of the activated metal ions in the first metal oxide phase.

In the wavelength conversion phosphor according to another aspect, the activated metal ions emitting fluorescence may be Ce³⁺, the first metal oxide phase may be Y₃Al₅ O₁₂, the second metal oxide phase may be Al₂O₃, and a concentration of the activated metal ions Ce³⁺ in the interface may be higher than an average concentration of the activated metal ions Ce³⁺ in the first metal oxide.

Hereinafter, a wavelength conversion phosphor according to an embodiment of the present disclosure will be explained with reference to the attached drawings. The same numerals are given to substantially the same members in the drawings.

### Embodiment 1

### <Wavelength Conversion Phosphor>

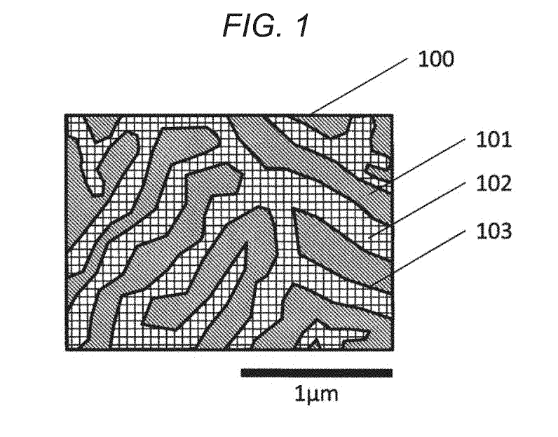

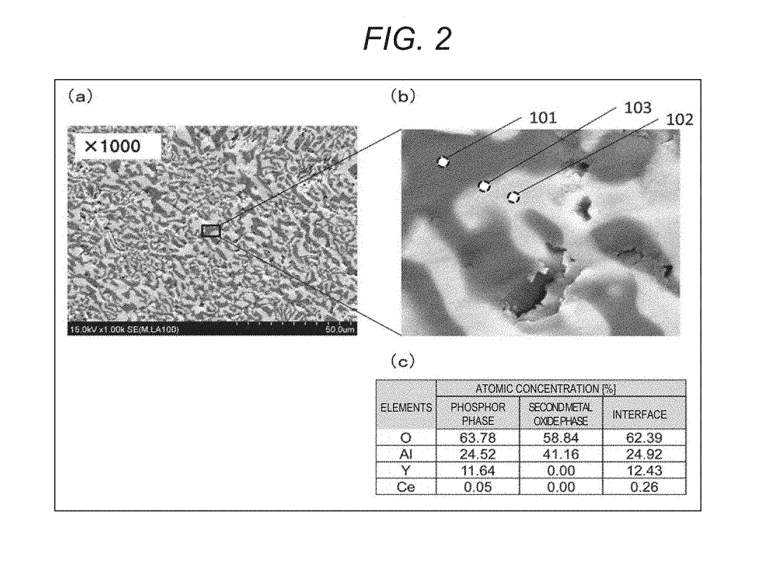

First, the wavelength conversion phosphor with excellent heat resistance and a high fluorescence output according to Embodiment 1 will be explained with reference to FIG. 1 and FIG. 2. FIG. 1 is a cross-sectional view of the wavelength conversion phosphor according to Embodiment 1.

A wavelength conversion phosphor 100 according to Embodiment 1 mainly includes two or more kinds of metal oxides. In FIG. 1, the wavelength conversion phosphor 100 includes a first metal oxide phase 101 as a phosphor phase containing activated metal ions which emit fluorescence and a second metal oxide phase 102 adjacent to the first metal oxide phase 101 at an interface 103. In the interface 103, the first metal oxide phase 101 as the phosphor phase and the second metal oxide phase 102 are adjacent to each other. The activated metal ions which emit fluorescence are concentrated more in the interface 103 than in the first metal oxide phase 101.

Here, the first metal oxide phase 101 as the phosphor phase containing the activated metal ions which emit fluorescence is, for example, (Y₁₋ₓ Ceₓ)₃—Al₅—O₁₂. The second metal oxide phase 102 is, for example, Al₂O₃. The activated metal ions which emit fluorescence are, for example, Ce³⁺. In the interface 103 between the phosphor phase 101 containing the activated metal ions which emit fluorescence and the adjacent second metal oxide phase 102, (Y₁₋ₓ Ceₓ)₃—Al₅—O₁₂ is formed, and 0.015≤x≤50.3.

A metal oxide formed of YAG/Al₂O₃ is a high-heat resistant material which can be used in a turbine of a jet engine and the like under a high-temperature environment of approximately 1500° C. The metal oxide has heat resistance in the same manner even when the activated metal ions which emit fluorescence are contained.

On the other hand, the first metal oxide phase 101 as the phosphor phase and the second metal oxide phase 102 form a eutectic structure on an interface. In the interface, the first metal oxide phase 101 and the second metal oxide phase 102 respectively have portions having dimensions of 1 μm or less. In the eutectic structure, the first metal oxide phase 101 and the second metal oxide phase 102 may have fine structures such as a dendritic shape, a needle shape, an island shape, a fern-leaf shape and a strip shape. In the interface 103 between the first metal oxide phase 101 as the phosphor phase and the second metal oxide phase 102, the activated metal ions which emit fluorescence are concentrated more than inside the first metal oxide phase 101.

The higher the content of the activated metal ions Ce³⁺ which emit fluorescence is, the more a certain wavelength of an excitation light source is absorbed, and a fluorescence output per a unit volume in the wavelength conversion phosphor 100 is increased.

(a) of FIG. 2 is a picture of cross-sectional observation of the wavelength conversion phosphor 100 shown in FIG. 1. (b) of FIG. 2 is an enlarged picture of cross-sectional observation of part of (a) of FIG. 2. (c) of FIG. 2 shows results of analyzing elemental compositions in a bright part, a dark part and an interface between the bright part and the dark park in (b) of FIG. 2.

The pictures of cross-sectional observation were imaged by using a scanning electron microscope (SEM) (SU-70 manufactured by Hitachi High-Technologies Corporation).

The analysis of elemental compositions was performed by using an energy dispersive X-ray analyzer (manufactured by Oxford Instruments plc).

According to SEM pictures ((a) of FIG. 2, (b) of FIG. 2) and results of elemental analysis ((c) of FIG. 2), the dark part shows the first metal oxide phase 101 (Y₁₋ₓCeₓ)₃—Al₅—O₁₂ as the phosphor phase containing the activated metal ions. The bright part shows Al₂O₃ as the second metal oxide phase 102. An interface between the bright part and the dark part is the interface 103 between the first metal oxide phase 101 as the phosphor phase containing the activated metal ions which emit fluorescence and the second metal oxide phase 102, where (Y₁₋ₓ Ceₓ)₃—Al₅—O₁₂ is formed.

According to the results of elemental analysis, atomic concentration of Ce is 0.05 at % in the first metal oxide phase 101 as the phosphor phase, Oat % in the second metal oxide phase 102 and 0.26 at % in the interface 103 between the first metal oxide phase 101 and the second metal oxide phase 102. It is found that Ce is contained in the interface 103 in high concentration.

As described above, the wavelength conversion phosphor 100 according to Embodiment 1 has excellent heat resistance and high fluorescence output as there is the interface 103 containing the activated metal ions Ce in high concentrations as the light emission center. Therefore, according to the wavelength conversion phosphor 100, even when light energy is concentrated in a minute area at the time of increasing a power density of excitation light by light convergence in the minute area in the lighting by laser excitation light, it is possible to realize a lighting device with high luminance by the phosphor having high heat resistance. Examples include laser headlights of the car, intelligent lighting and endoscope lighting.

### <Manufacturing Method of Wavelength Conversion Phosphor>

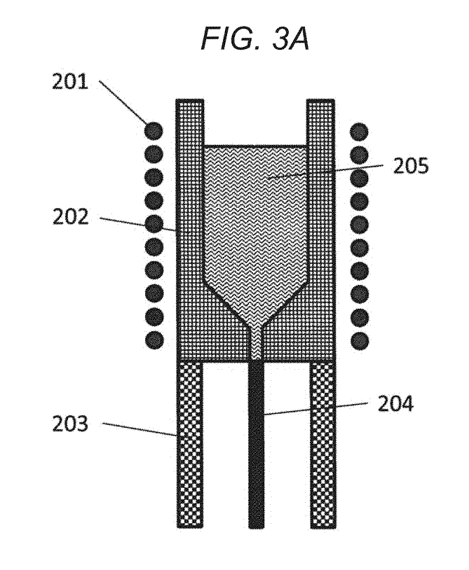

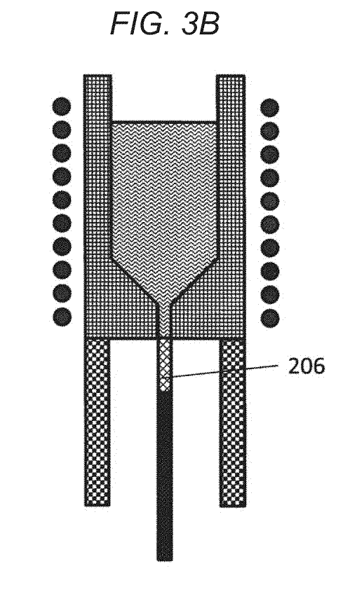

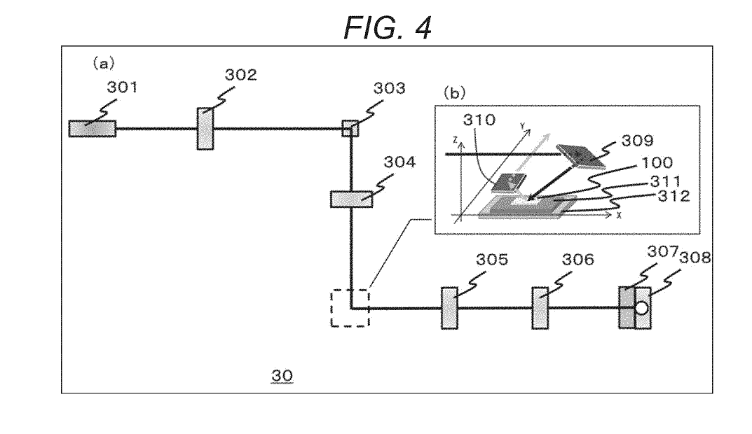

Next, a method of manufacturing the wavelength conversion phosphor 100 will be explained. FIG. 3A is a schematic view showing a device and a process for manufacturing the wavelength conversion phosphor according to Embodiment 1, which is an outline diagram showing a state where a melt is allowed to contact a seed crystal. FIG. 3B is a schematic view showing a device and a process for manufacturing the wavelength conversion phosphor according to Embodiment 1, which is an outline diagram showing a state where the seed crystal is pulled down to grow a crystal on the seed crystal.

A unidirectional rapidly-cooling solidification method is the most preferable. FIG. 3A and FIG. 3B show processes of the unidirectional rapidly-cooling solidification method. A manufacturing method of the wavelength conversion phosphor 100 according to Embodiment 1 will be explained with reference to FIG. 3A and FIG. 3B.

The wavelength conversion phosphor 100 according to Embodiment 1 can be obtained by molding a given metal oxide and then solidifying the metal oxide. For example, a given amount of first metal oxide forming the phosphor phase 101 and a second metal oxide forming the second metal oxide phase 102 are put in a crucible 202 held in a given temperature, then, cooled and solidified while controlling a cooling temperature.

(1) First, the given amount of first metal oxide forming the phosphor phase 101, the second metal oxide forming the second metal oxide phase 102 and the metal oxide containing the activated metal ions are mixed, and mixed powder is adjusted.

(2) Next, the mixed powder is put into the crucible 202 and is heated to a given temperature to be melted by using, for example, a high-frequency furnace 201. The environment of heating is preferably a nitrogen atmosphere.

(3) A metal oxide 205 melted inside the crucible is solidified by being allowed to contact the seed crystal 204 (FIG. 3A). When the seed crystal 204 is pulled down at a given speed, the melted metal oxide 205 flows down through a hole of the crucible 202 and solidified, thereby growing a crystal 206 (FIG. 3B).

The cooling speed for solidification is controlled by a heater 203, and structure shapes and sizes of the first metal oxide phase 101 as the phosphor phase and the second metal oxide phase 102 are determined.

In the wavelength conversion phosphor 100 according to Embodiment 1, intervals between the first metal oxide phase 101 as the phosphor phase and the second metal oxide phase 102 in the eutectic structure of the interface can be controlled by the cooling speed, which are preferably 0.01 to 1 μm.

The first metal oxide phase may include one or more kinds of metal oxides selected from a group of La₂O₃, Y₂O₃, Y₃Al₅O₁₂, CeO₂, Nd₂O₃, Gd₂O₃, Eu₂O₃, Tb₄O₇, Ho₂O₃, Er₂O₃, Tm₂O₃, Yb₂O₃, Lu₂O₃ and Cr₂O₃.

The second metal oxide phase may include one or more kinds of metal oxides selected from a group of Al₂O₃, MgO, SiO₂, TiO₂, ZrO₂, Y₂O₃, MnO, Nb₂O₅, Cr₂O₃, SrO, ZnO and SnO₂.

The activated metal ions which emit fluorescence may include one or more kinds of metal ions selected from a group of La³⁺, Y³⁺, Ce³⁺, Nd³⁺, Gd³⁺, Eu²⁺, Eu³⁺, Tb²⁺, Ho³⁺, Er³⁺, Tm³⁺, Tb³⁺ and Lu³⁺.

In the wavelength conversion phosphor 100 according to Embodiment 1, as the metal oxide forming the first metal oxide phase 101 as the phosphor phase, for example, Y₂O₃ powder is used, as the metal oxide containing the activated metal ions which emit fluorescence, for example, CeO₂ powder is used, and as the metal oxide forming the second metal oxide phase 102, for example, Al₂O₃ powder is used as a raw material.

### Examples and Comparative Examples

Hereinafter, the wavelength conversion phosphor and the manufacturing method thereof according to the embodiment will be specifically explained by using examples and comparative examples.

### Example 1

A manufacturing method of the wavelength conversion phosphor according to Example 1 will be explained.

(a) First, in order to blend a metal oxide forming the first metal oxide phase 101 as the phosphor phase, Y₂O₃ and CeO₂ are weighed and mixed so that Ce³⁺ is 0.05 to 10 at % with respect to an atomic fraction of Yttrium (Y).

(b) Next, (Y₁₋ₓ Ceₓ)₃—Al₅—O₁₂ of the phosphor phase 101 and Al₂O₃ of the second metal oxide phase 102 have the eutectic structure when they are solidified. In order to obtain the fine structure, two kinds of metal oxide powder are weighed and mixed at a ratio of (Y₁₋ₓ Ceₓ)₃—Al₅—O₁₂:Al₂O₃=51:49 (mol).

(c) The above powder is put into the crucible made of iridium and heated to approximately 2000° C. in a high-frequency furnace to be melted. The melting is performed in a nitrogen atmosphere at this time.

In the crucible 202, the metal oxide powder is melted. Moreover, the viscosity is adjusted by adjusting the temperature of the melt and a hole diameter in a lower surface part of the crucible 202 is adjusted so as to prevent the melt from flowing out from the hole portion formed in the lower surface part of the crucible 202.

As the conditions are set as described above, part of the melt protrudes from the hole portion formed in the lower surface part of the crucible 202 in a dome shape by the surface tension of the melt and the hold portion formed in the lower surface part of the crucible 202.

(d) The seed crystal 204 is an origination for solidifying the melt and growing the crystal. Then, when the seed crystal 204, for example, sapphire Al₂O₃, is allowed to rise to allow the seed crystal 204 to contact the dome shaped melt formed in the lower surface part of the crucible 202, the melt leaks and spreads at a tip end part of the seed crystal 204 (FIG. 3A). The melt is solidified at the same time as leaking and spreading on the seed crystal 204.

(e) When the above seed crystal 204 is pulled down from the state where the seed crystal 204 contacts the dome shaped melt, the molten metal oxide inside the crucible 202 flows down through the hole of the crucible 202 and is solidified. A crystal grows on the seed crystal 204 (FIG. 3B). A speed at which the crystal is pulled down at this time is 1 to 10 mm/min, and the crystal grows in a state of being cooled and solidified relatively rapidly as crystal growth.

Here, in a case where, for example, the solidification is sufficiently slow, and the crystal grows in a state close to the steady state, approximately 0.06 at % of Ce³⁺ which is the theoretical limit with respect to the Y (Yttrium) site of YAG as a matrix is contained.

On the other hand, as the crystal does not grow in an equilibrium state in the case of rapid solidification, an amount of Ce³⁺ contained in the Y site of the YAG is small. Additionally, the oxide phase of YAG and the oxide phase of Al₂O₃ are solidified as the eutectic structure at 1890° C. in the case of the rapid solidification, therefore, an amount of Ce³⁺ displaced to the Y site of the oxide phase of YAG is smaller than that in a case of gradual cooling close to the steady state. That is, Ce³⁺ is solidified in a more condensed state so as to be taken into the interface between the two oxide phases.

The wavelength conversion phosphor 100 in which the activated metal ions Ce³⁺ which emit fluorescence are condensed in the interface 103 between the phosphor phase (first metal oxide phase 101) containing the activated metal ions Ce³⁺ which emit fluorescence and the adjacent second metal oxide phase 102 by the above cooling process in the non-steady state.

Measurement results of the structure size, Ce³⁺ content and internal quantum efficiency in Examples and Comparative Examples of the wavelength conversion phosphor 100 created as described above are shown in Table 1.

TABLE 1

| | Pull-down | | | Internal quantum |
|---|---|---|---|---|
| | speed | Structure size | Ce³⁺ | efficiency |
| | [mm/min] | [μm] | content | [%] |
| Comparative | 0.08 | 15.8 | low | 94.9 |
| Example 1 | | | | |
| Comparative | 0.10 | 12.3 | low | 93.5 |
| Example 2 | | | | |
| Comparative | 0.20 | 10.2 | low | 92.3 |
| Example 3 | | | | |
| Comparative | 0.5 | 3.2 | middle | 95.2 |
| Exampe 4 | | | | |
| Example 1 | 1.00 | 1.0 | high | 94.2 |
| Example 2 | 3.00 | 0.8 | high | 95.2 |
| Example 3 | 5.00 | 0.7 | high | 96.3 |
| Example 4 | 10.00 | 0.4 | high | 92.1 |

| | | |
|---|---|---|
| Comparative | 15.00 | Sample unavailable |
| Example 5 | | |

The structure size of the eutectic structure in the interface takes an average value obtained by measuring widths of the structures of respective phosphor phase 101 and the second metal oxide phase 102 at 20 points with a visual field of 200 magnification by using a common microscope capable of measuring a length. That is, the structure size is an average value of widths in a short-side direction, not a longitudinal direction of each structure.

Concerning the Ce³⁺, content, quantitative analysis was performed by using an electron microscope (SU-70: manufactured by Hitachi High-Technologies Corporation) and the energy dispersive X-ray analyzer (manufactured by Oxford Instruments plc).

In Comparative Examples 1 to 5 and Examples 1 to 4, the wavelength conversion phosphor 100 was fabricated by controlling a pull-down speed of the crystal, namely, the solidification speed of the crystal.

A laser having a wavelength of 450 nm was used as an excitation light source for measuring the internal quantum efficiency. A commonly-used system QE-SA100/LD (manufactured by Lambda Vision Inc.) using an integrating sphere and a spectroscope was used. The internal quantum efficiency was calculated by dividing an integrated value of excitation light spectral intensity from a laser light source as the excitation light source by an integrated value of emission wavelength spectral intensity the wavelength of which was converted.

$$internal quantum efficiency ( \% ) = \frac{integral value of light emission spectral intensity}{integral value of excitation light spectral intensity} \times 100$$

Here, the internal quantum efficiency indicates efficiency in which absorbed excitation light is converted into fluorescence.

Blending was performed so that an atomic fraction of Ce with respect to Y was 0.1 at % both in Comparative Examples and Examples. A contact surface of the crucible was processed so that an external size became 5 mm square.

As the pull-down speeds are gradual in Comparative Examples 1 to 4, which are 0.08 to 0.5 mm/min, the phosphor phase 101 and the second metal oxide phase 102 are gradually solidified. The structure sizes of the eutectic structures in the interfaces are respectively 15.8 μm, 12.3 μm, 10.2 μm and 3.2 μm in Comparative Examples 1, 2, 3 and 4.

The structure sizes of the eutectic structures are 1.0 μm, 0.8 μm, 0.7 μm and 0.4 μm in Examples 1, 2, 3 and 4, which are more minute structures than those of Comparative Examples 1 to 4.

The cooling speed is faster in Examples 1 to 4 than in Comparative Examples 1 to 4. Therefore, the structures are miniaturized and the structure sizes in the eutectic structure include portions of 1 μm or less in the interface 103 between the first metal oxide phase 101 as the phosphor phase and the adjacent second metal oxide phase 102.

According to the above result, the structure size of the first metal oxide phase 101 as the phosphor phase and the second metal oxide phase 102 is miniaturized in the eutectic structure of the interface due to the pull-down speed. This means that the area of the interface 103 between the first metal oxide phase 101 and the second metal oxide phase 102 is increased as the structure size becomes minute.

Additionally, the Ce³⁺ content was detected in higher concentration as the pull-down speed is reduced and the structure size becomes small.

It is found that internal quantum efficiencies are substantially equivalent both in Comparative Examples 1 to 4 and Examples 1 to 4. There is a possibility that a phenomenon in which light emission intensity of the phosphor is reduced (concentration quenching) occurs with the increase of concentration of the activated metal Ce³⁺ as the light emission center. However, the phenomenon does not occur in the embodiment according to the above.

The above measurement results of the structure size, Ce³⁺ content and internal quantum efficiency, it is found that the area of the interface 103 between the first metal oxide phase 101 as the phosphor phase and the second metal oxide phase 102 is increased as the structure size becomes small, and that Ce³⁺ is highly concentrated on the interface.

As the internal quantum efficiencies are substantially equivalent both in Comparative Examples and Examples, the phosphor absorbs excitation energy of the laser light source and converts the energy into light emission energy even when Ce³⁺ content is increased. That is, it is found that Ce³⁺ activated metal ions absorbing the blue wavelength of 450 nm and converting the wavelength into the yellow wavelength of 570 to 590 nm to emit fluorescence is contained in high concentrations in Examples 1 to 4.

The higher Ce³⁺ content there is, the more the light emission centers converting the wavelength exist. That is, it is found that the fluorescence output can be increased as Ce³⁺ content becomes high.

In Comparative Example 5, the pull-down speed was 15 mm/min and rapid cooling was performed, however, the seed crystal part and the melt part was separated in the middle of crystal growth, therefore, creation of a sample was not possible.

Measurement results of the pull-down speed and fluorescent outputs in Examples and Comparative Examples of the wavelength conversion phosphor 100 obtained by measuring weights so that Ce³⁺ as the activated metal ions emitting fluorescence has a given blending amount with respect to Y in the atomic fraction are shown in Table 2.

TABLE 2

| | Pull-down speed | Ce³⁺ co | Fluorescence output |
|---|---|---|---|
| | [mm/min] | [at % vs Y] | [mW] |
| Comparative | 3.00 | 0.05 | 23.8 |
| Example 6 | | | |
| Comparative | 0.08 | 0.05 | 26.8 |
| Example 7 | | | |
| Example 5 | 3.00 | 0.05 | 31.5 |
| Example 6 | 3.00 | 0.1 | 32.0 |
| Example 7 | 3.00 | 1 | 32.6 |
| Example 8 | 3.00 | 5 | 33.0 |
| Comparative | 3.00 | 10 | Sample unavailable |
| Example 8 | | | |

In Examples 5 to 8, the pull-down speed was fixed to 3.00 mm/min. Two kinds of metal oxide power Y₂O₃ and Al₂O₃ were weighed and mixed so that Ce³⁺ as the activated metal ions emitting fluorescence in a single crystal of Y₃Al₅O₁₂ had values in the Table with respect to Y in the atomic fraction, which were melted in the crucible and crystals were grown by the pulling method to thereby obtain the wavelength conversion phosphor 100.

The blending method differs from that of the wavelength conversion phosphor 100 only in Comparative Example 6. In Comparative Example 6, two kinds of metal oxide power Y₂O₃ and Al₂O₃ were weighed and mixed so that Ce³⁺ as the activated metal ions emitting fluorescence was 0.05 at % with respect to Y in the atomic fraction in the single crystal of Y₃Al₅O₁₂, which were melted in the crucible and the crystal was grown by the pulling method.

### <Measurement System of Fluorescence Output>

(a) of FIG. 4 is an outline diagram showing a structure of a measurement device 30 for measuring the fluorescence output (external quantum efficiency) of the wavelength conversion phosphor. (b) of FIG. 4 is a partial outline diagram showing a structure including a reflection mirror 309, the wavelength conversion phosphor 100, a mirror 310, a reflector 311 and a heater 312 arranged between a lens 304 and a lens 305 of the measurement device shown in (a) of FIG. 4.

In the measurement device 30, white light as actual lighting can be taken out by irradiating the wavelength conversion phosphor 100 with the excitation light source, and the fluorescence output can be measured. In the measurement device, a laser 301 of 445 nm with a 1.5 W output is used as the excitation light source. Laser light passes through a polarizing plate 302 and is refracted at 90 degrees by a prism 303 to be converged by using the lens 304 of f200. The phosphor is installed on the reflector 311 on which Ag is deposited, and a total reflection component is cut by using the reflection mirror 309, therefore, the wavelength conversion phosphor 100 is irradiated with laser light converged to 40.6 mm at a certain angle. The mirror 310 is installed just on the phosphor and the light is collimated by the lens 305 of f75, and further, light converged by a lens 306 of f100 is measured as a fluorescence output through a blue cut filter 307 on the way by using a power meter 308 (manufactured by Ophir Optronics). The wavelength conversion phosphor 100 is irradiated with the converged laser light by using the reflection mirror 309 at approximately 45 degrees.

Relative comparison was performed between Comparative Examples 6 to 8 and Examples 5 to 8.

### Comparative Example 6

In Comparative Example 6, a YAG single crystal with 0.05 at % of the activated metal ions Ce³⁺ was used, and the fluorescence output was 23.8 mW.

### Comparative Example 7

In Comparative Example 7, the wavelength conversion phosphor 100 was formed at a pull-down speed of 0.08 mm/min. When the eutectic structure size was measured, the structure size was equivalent to the condition of 15.8 μm, and the fluorescence output was 26.8 mW.

In Examples 5 to 8, a tendency in which the fluorescence output was increased as the activated metal ions Ce³⁺, were increased with respect to Y was checked, and excellent fluorescence output could be obtained. This is because Ce³⁺ as a light emitting point is concentrated on the interface 103 between the first metal oxide phase 101 as the phosphor phase and the adjacent second metal oxide phase 102.

### Comparative Example 8

In Comparative Example 8, two kinds of metal oxide power Y₂O₃ and Al₂O₃ were weighed and mixed so that Ce³⁺ as the activated metal ions emitting fluorescence was 10 at % with respect to Y in the atomic fraction in the single crystal of Y₃Al₅O₁₂, then melted in the crucible 202 to try to grow the crystal by the pulling method. Although the mixed oxide powder was melted in the crucible 202, a melt from the hole on the lower surface of the crucible did not form a dome shape, therefore, creation of a sample was abandoned.

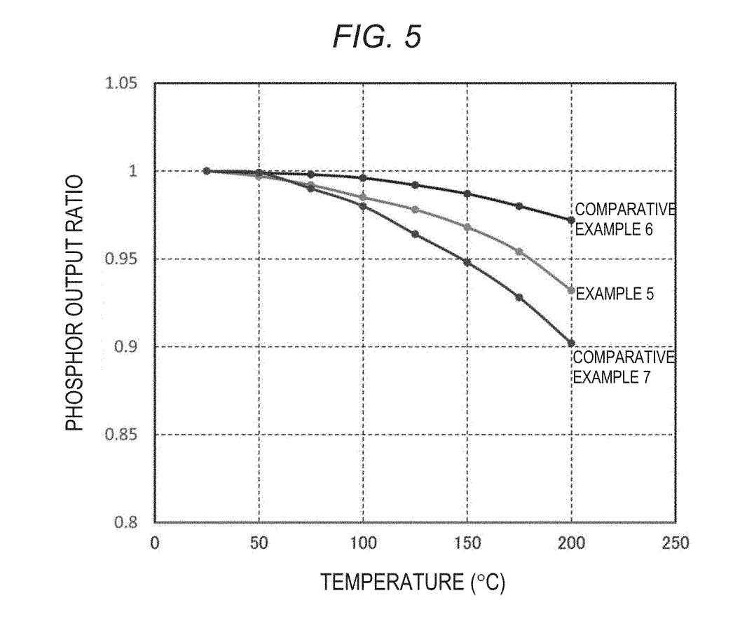

Next, the temperature of the wavelength conversion phosphor 100 was increased and variations in fluorescence output with respect to the temperature were measured. In the measurement device shown in FIG. 4, the temperature of the wavelength conversion phosphor 100 was increased to a given temperature by heating the heater 312. FIG. 5 is a graph showing variations of a fluorescence output ratio with respect to temperatures in Comparative Examples and Example.

The evaluation was performed in a temperature range from a room temperature to 200° C., and fluorescence outputs at given temperatures with respect to the fluorescence output at the room temperature were measured. The vertical axis represents the ratio between fluorescence output at the room temperature and fluorescence outputs at given temperatures and the horizontal axis represents the temperature.

In Comparative Example 6, a fluorescence output ratio was 97% at 200° C.

In Comparative Example 7, a fluorescence output ratio was 90% at 200° C.

In Example 5, a fluorescence output ratio was 93% at 200° C.

In Comparative Example 6, reduction in the fluorescence output ratio is small even at high temperatures, however, the fluorescence output at the room temperature is low, which is 23.8 mW as shown in Table 2. Accordingly, the fluorescence output is 23.1 mW at 200° C.

On the other hand, in Example 5, the fluorescence output at the room temperature is 31.5 mW and the fluorescence output is 29.3 mW also at 200° C., which is higher than that of Comparative Example 6. It is found that the fluorescence output at high temperatures is excellent.

It can be confirmed that conversion efficiency exceeds 90% in any condition in Examples 5 and 6. It is also found that functions as the wavelength conversion phosphor 100 can be sufficiently fulfilled without problems until the temperature of the phosphor reaches 200° C.

As preconditions for comparing the above respective samples, measurements were performed while adjusting the thickness of the wavelength conversion phosphor 100 so that color coordinates are close to (X, Y)=(0.31, 0.34) and a color temperature is close to approximately 6000K.

In the present disclosure, suitable combinations of arbitrary embodiments and/or examples may occur in the above-described various embodiments and/or examples, and advantages obtained by respective embodiments and/or examples can be realized.

The wavelength conversion phosphor according to the present disclosure has the wavelength conversion function, which is excellent in heat resistance and high in fluorescence output. In particular, performance of obtaining white light by using the blue laser diode (LD) emitting high excitation energy as the excitation light source is excellent, therefore, the present disclosure has a high practical value as an application of the phosphor with respect to high luminance of a projector as a light source and for distant lighting as car headlights.

What is claimed is:

1. A wavelength conversion phosphor comprising:
a first metal oxide phase as a phosphor phase containing activated metal ions which emit fluorescence; and
a second metal oxide phase adjacent to the first metal oxide phase through an interface,
wherein a concentration of the activated metal ions in the interface is higher than a concentration of the activated metal ions contained in the first metal oxide phase.

2. The wavelength conversion phosphor according to claim 1,
wherein the first metal oxide phase and the second metal oxide phase form a eutectic structure on the interface.

3. The wavelength conversion phosphor according to claim 2,
wherein the first metal oxide phase and the second metal oxide phase respectively have portions having dimensions of 1 μm or less in the eutectic structure.

4. The wavelength conversion phosphor according to claim 1,
wherein the activated metal ions which emit fluorescence include one or more kinds of metal ions selected from a group of La³⁺, Y³⁺, Ce³⁺, Nd³⁺, Gd³⁺, Eu²⁺, Eu³⁺, Tb²⁺, Ho³⁺, Er³⁺, Tm³⁺, Tb³⁺ and Lu³⁺,
the first metal oxide phase includes one or more kinds of metal oxides selected from a group of La₂O₃, Y₂O₃, Y₃Al₅O₁₂, CeO₂, Nd₂O₃, Gd₂O₃, Eu₂O₃, Tb₄O₇, Ho₂O₃, Er₂O₃, Tm₂O₃, Yb₂O₃, Lu₂O₃ and Cr₂O₃,
the second metal oxide phase includes one or more kinds of metal oxides selected from a group of Al₂O₃, MgO, SiO₂, TiO₂, ZrO₂, Y₂O₃, MnO, Nb₂O₅, Cr₂O₃, SrO, ZnO and SnO₂, and
the activated metal ions are contained in the interface in higher concentration than an average concentration of the activated metal ions in the first metal oxide phase.

5. The wavelength conversion phosphor according to claim 4,
wherein the activated metal ions emitting fluorescence are Ce³⁺, the first metal oxide phase is Y₃Al₅O₁₂, and the second metal oxide phase is Al₂O₃, and
a concentration of the activated metal ions Ce³⁺ in the interface is higher than an average concentration of the activated metal ions Ce³⁺ in the first metal oxide.

6. The wavelength conversion phosphor according to claim 4,
wherein (Y₁₋ₓCeₓ)₃—Al₅—O₁₂ forms in the interface between the phosphor phase containing the activated metal ions which emit fluorescence and the second metal oxide phase adjacent to the first metal oxide phase, and 0.015≤x≤0.3.
